(19) United States
(12) Patent Application Publication
(10) Pub. No.: US 2015/0235842 A1
(43) Pub. Date: Aug. 20, 2015

(54) TRANSISTOR AND METHOD FOR MANUFACTURING THE SAME

(71) Applicant: TOKYO ELECTRON LIMITED, Tokyo (JP)

(72) Inventors: Kenichi HARA, Nirasaki City (JP); Shuji AZUMO, Nirasaki City (JP)

(21) Appl. No.: 14/621,815

(22) Filed: Feb. 13, 2015

(30) Foreign Application Priority Data
Feb. 17, 2014 (JP) 2014-027522

(51) Int. Cl. H01L 21/02; H01L 29/16; H01L 21/311; H01L 29/78

(52) U.S. Cl. CPC H01L 21/02266; H01L 29/78; H01L 29/1608; H01L 21/31133

(57) ABSTRACT

A method for manufacturing a transistor includes irradiating an oxygen gas cluster ion beam onto a surface layer of a substrate which is made of silicon carbide and includes a channel area to become a channel to form a thin interface oxide film.

### CROSS-REFERENCE TO RELATED APPLICATION

This application claims priority to Japanese Patent Application No. 2014-027522, filed on Feb. 17, 2014, in the Japan Patent Office, the disclosure of which is incorporated herein in its entirety by reference.

### TECHNICAL FIELD

The present disclosure relates to a transistor including a gate oxide film which is in contact with a channel made of silicon carbide and a method for manufacturing the same.

### BACKGROUND

Silicon carbide (SiC) has 3 eV of a band gap and may be used as a material for making a semiconductor. Since silicon carbide is a high resistance semiconductor material with ten times higher dielectric breakdown voltage than that of silicon (Si), a study has been conducted for using silicon carbide for devices for aerospace or power devices having a transistor structure in which a large electric current flows.

The devices described above are obtained from SiC wafers. After being cut from a SiC ingot, the SiC wafer is polished with abrasive grain. Since the abrasive grain used in the polishing is in a micro-level size, minute unevenness, e.g., equal to or less than 1 μm in height may remain on the surface of the SiC wafer.

In the case of a silicon wafer, the minute unevenness that remains after polishing with abrasive grain can be removed by means of a polishing accompanied by chemical reactions such as CMP (Chemical Mechanical Polishing) and the like. However, since the bonding between silicon and carbon (C) is very strong, it is difficult to remove the remaining minute unevenness using CMP or the like in the silicon carbide wafer.

In a process of producing a transistor from a Sic wafer, the minute unevenness described above becomes uneven at an interface between a channel made of silicon carbide and a gate oxide film in the transistor. Since the unevenness causes high interface state density, channel mobility and channel conductance decrease.

In addition, when a semiconductor device is produced from a Sic wafer, a heat treatment by hydrogen (H₂) around 1700 degrees C. is needed. However, during this process, damage may be caused on the channel because of a loss of silicon in the wafer.

Further, a gate electrode in the transistor may be a flat plate-shaped electrode (planar electrode). However, three-dimensional gate electrodes showing a V-shaped groove or a U-shaped groove may exist since the channel is lengthened by lengthening the corresponding gate electrode. Although these three-dimensional gate electrodes can be obtained by etching a surface layer of the wafer, the etching may cause damage on the surface layer of the wafer.

The damage described above may lead to a decrease in channel conductance.

On the other hand, silicon carbide can be oxidized. In this regard, a study has been conducted for forming a gate oxide film in direct contact with a channel by thermally oxidizing the surface layer of the wafer that constitutes the channel. In this case, when silicon oxide is generated by thermally oxidizing silicon carbide, sometimes carbon remains in the oxide film. This carbon residue may generate impurities due to combining with other elements. These impurities disrupt smoothing the interface between the oxide film and the channel and make high interface state density. This causes a decrease in channel mobility and channel conductance.

To avoid the above-mentioned problems of a decrease in the channel mobility resulting from high interface state density, using a two-stage oxidation method in which temperature is changed during a formation of an oxide film on a surface layer of a wafer by thermal oxidation, or introducing nitrogen (N) or phosphorus (P) to a channel has been studied. However, those ways can not sufficiently improve the interface state density of the channel or the channel mobility. That is, a satisfactory channel conductance can not be obtained.

### SUMMARY

The present disclosure provides a transistor in which a decrease of channel conductance can be prevented and a method for manufacturing the transistor.

The method for manufacturing a transistor according to one embodiment of the present disclosure includes irradiating an oxygen gas cluster ion beam onto a surface layer of a substrate made of silicon carbide and including a channel area to become a channel to form a thin interface oxide film.

The transistor according to another embodiment of the present disclosure includes a channel area to become a channel, and a gate oxide film formed on the channel area, wherein the gate oxide film includes a thin interface oxide film formed on the channel area and an oxide film formed on the thin interface oxide film, wherein the thin interface oxide film is formed by irradiation of an oxygen gas cluster ion beam onto the surface layer of a substrate made of silicon carbide and including the channel area.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view schematically showing a configuration of a substrate processing apparatus performing a transistor manufacturing method according to an embodiment of the present disclosure.

FIG. 2 is a sectional view schematically showing a configuration of a GCIB irradiation apparatus shown in FIG. 1.

FIGS. 3A and 3B are views for explaining irradiation of an oxygen-GCIB onto silicon carbide.

FIG. 4 is a sectional view schematically showing a configuration of a MOSFET manufactured by performing a transistor manufacturing method according to the present embodiment.

FIGS. 5A to 5D are process diagrams illustrating a transistor manufacturing method according to the present embodiment.

FIGS. 6A to 6G are process diagrams illustrating a modification of the transistor manufacturing method shown in FIGS. 5A to 5D.

FIGS. 7A and 7B are views explaining an oxygen-GCIB irradiation in a method for manufacturing a transistor including three-dimensional gate electrodes, wherein FIG. 7A shows a case of a gate electrode having a V-shaped groove whereas FIG. 7B shows a case of a gate electrode having a U-shaped groove.

### DETAILED DESCRIPTION

Reference will now be made in detail to various embodiments, examples of which are illustrated in the accompanying drawings. In the following detailed description, numerous specific details are set forth in order to provide a thorough understanding of the inventive aspects of this disclosure. However, it will be apparent to one of ordinary skill in the art that the inventive aspects of this disclosure may be practiced without these specific details. In other instances, well-known methods, procedures, systems, and components have not been described in detail so as not to unnecessarily obscure aspects of the various embodiments.

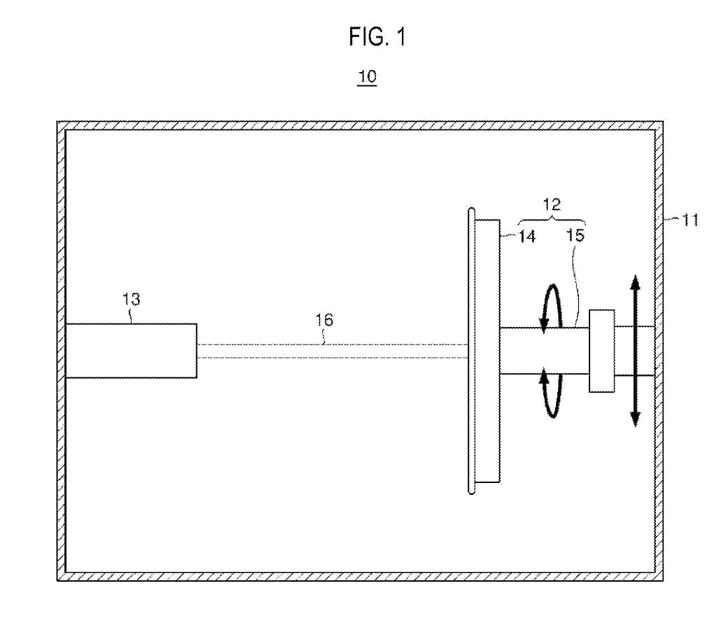

FIG. 1 is a sectional view schematically showing a configuration of a substrate processing apparatus performing a transistor manufacturing method according to one embodiment.

In FIG. 1, the substrate processing apparatus 10 includes a chamber 11 configured to accommodate a semiconductor wafer W (hereinafter referred to as “wafer”), a wafer holding unit 12 installed on an inside surface of the chamber 11, and a GCIB irradiation apparatus 13 installed on an inside surface of a lateral wall of the chamber 11 to face the wafer holding unit 12.

The wafer holding unit 12 includes a stage 14 attracting the wafer W by electrostatic force or the like, and an axial-shaped base 15 supporting the stage 14. The base 15 is configured to be movable along the inside surface of the chamber 11 and be rotatable around an axis thereof. Accordingly, the base 15 can make a predetermined part of the wafer W held on the stage 14 face the GCIB irradiation apparatus 13 in a face to face manner. Further, the GCIB irradiation apparatus 13 irradiates an oxygen-GCIB (Gas Cluster Ion Beam) 16 along the horizontal direction in FIG. 1.

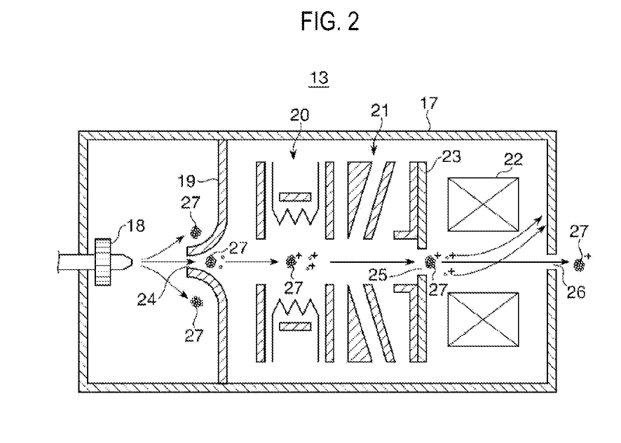

FIG. 2 is a sectional view schematically showing a configuration of the GCIB irradiation apparatus shown in FIG. 1.

In FIG. 2, the GCIB irradiation apparatus 13 includes a cylindrical body 17 approximately horizontally arranged and having a depressurized inside, a nozzle 18 arranged at one end portion of the body 17, a plate-shaped skimmer 19, an ionizer 20, an accelerator 21, a permanent magnet 22, and an aperture plate 23.

The nozzle 18 is arranged along the center axis of the body 17 and discharges an oxygen gas along the center axis thereof. The skimmer 19 is arranged to block a cross-section of the body 17. The central part of the skimmer 19 protrudes toward the nozzle 18 along the center axis of the body 17. The protrusion of the central part includes a skimmer aperture 24 on the top portion of the protrusion. The aperture plate 23 is also arranged to block a cross-section of the body 17 and includes an aperture hole 25 at a portion corresponding to the center axis of the body 17. The other end portion of the body 17 also includes an aperture hole 26 at a portion corresponding to the center axis of the body 17.

Each of the ionizer 20, the accelerator 21 and the permanent magnet 22 radially extends about the center axis of the body 17. The ionizer 20 emits electrons by heating a filament in it. The accelerator 21 generates a potential difference along the center axis of the body 17. The permanent magnet 22 generates a magnetic field near the center axis of the body 17. The voltage provided to the accelerator 21 for generating the potential difference will be referred to as “acceleration voltage”.

In the GCIB irradiation apparatus 13, the nozzle 18, the skimmer 19, the ionizer 20, the accelerator 21, the aperture plate 23 and the permanent magnet 22 are arranged in this order from the one end portion of the body 17 (left side of the drawing) to the other end portion (right side of the drawing).

When the nozzle 18 discharges an oxygen gas inside the depressurized body 17, the oxygen gas increases in volume rapidly. Then under rapid adiabatic expansion, the oxygen molecules are rapidly cooled. When each of the oxygen molecules is rapidly cooled, the kinetic energy decreases. Therefore, the oxygen molecules closely contact with each other by intermolecular force (van der Waals force) between the oxygen molecules. Accordingly, a plurality of oxygen gas cluster 27 including numerous oxygen molecules is formed.

The skimmer 19 only selects the oxygen gas cluster 27 that moves along the center axis of the body 17 among the plurality of oxygen gas clusters 27 using the skimmer aperture 24. The ionizer 20 ionizes the oxygen gas cluster 27 by smashing electrons to the oxygen gas cluster 27 moving along the center axis of the body 17. The accelerator 21 accelerates the ionized oxygen gas cluster 27 toward the other end portion of the body 17 by the potential difference. The aperture plate 23 only selects the oxygen gas cluster 27 moving along the center axis of the body 17 among the accelerated oxygen gas clusters 27 using the aperture hole 25. With the permanent magnet 22, relatively small oxygen gas cluster 27 (including monomers of the ionized oxygen molecules) is changed in path thereof due to the magnetic field. In the permanent magnet 22, although comparatively large oxygen gas cluster 27 is also influenced by the magnetic field, the large oxygen gas cluster 27 keeps moving along the center axis of the body 17, not changing its path because of the large mass thereof.

After passing through the permanent magnet 22, the comparatively large oxygen gas clusters 27 are emitted out of the body 17 as an oxygen-GCIB through the aperture hole 26 of the other end portion of the body 17, and then irradiated toward the wafer W.

As an oxygen source for the oxygen gas cluster 27, in addition to the oxygen gas as set forth above, a gas including oxygen, e.g., carbon monoxide (CO), carbon dioxide (CO₂) or nitrous oxide (N₂O) can be used.

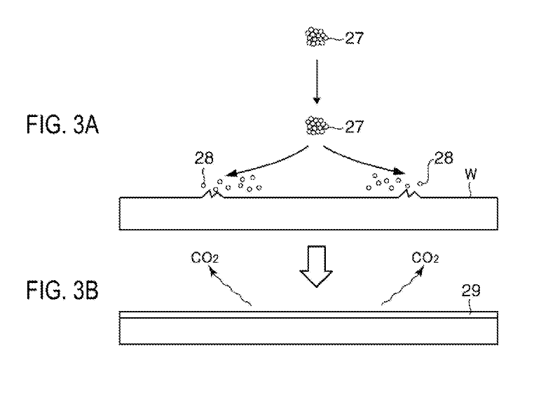

FIGS. 3A and 3B are views for explaining irradiation of an oxygen-GCIB onto silicon carbide.

In FIGS. 3A and 3B, when the oxygen-GCIB 16 is irradiated onto a wafer W made of silicon carbide and the oxygen gas cluster 27 smashes against the wafer W, the oxygen gas cluster 27 is decomposed into the oxygen molecules 28 because the oxygen molecule 28 has a small van der Waals force. The decomposed oxygen molecules 28 are scattered along the surface layer of the wafer W and actively sputter protrusion portions on the wafer W (lateral sputtering, see FIG. 3A). In other words, since the sputtering is conducted by the oxygen molecules 28, the protrusion portions having a molecular level size can be removed from the surface layer of the wafer W. As a result, it is possible to flatten the surface layer of the wafer W at a molecular level size accuracy.

Further, when the oxygen gas cluster 27 smashes onto the wafer W, the oxygen molecules 28 oxidize silicon carbide and a thin interface oxide film 29 is formed on the surface layer (interface) of the wafer W (see FIG. 3B). During the forming of the interface oxide film 29, since a combination of carbon and oxygen is accelerated in the wafer W by kinetic energy of the oxygen gas cluster 27, carbon contained in the interface oxide film 29 is emitted as carbon dioxide. As a result, the interface oxide film 29 in which carbon hardly ever remains can be obtained.

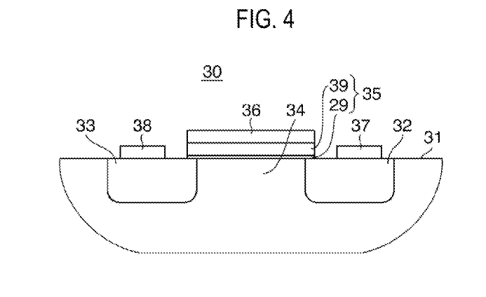

FIG. 4 is a sectional view schematically showing a configuration of a MOSFET (Metal Oxide Semiconductor Field Effect Transistor) manufactured by performing a transistor manufacturing method according to the present embodiment.

In FIG. 4, the MOSFET 30 includes a SiC base 31, a drain area 32 and a source area 33 formed apart from each other in the surface layer of the SiC base 31, a channel area 34 interposed between the drain area 32 and the source area 33, a gate oxide film 35 formed on the channel area 34, a gate electrode 36 formed on the gate oxide film 35, a drain electrode 37 and a source electrode 38 formed on the drain area 32 and the source area 33, respectively.

In the MOSFET 30, the gate oxide film 35 includes a thin interface oxide film 29 which is directly formed on the channel area 34, and a thick coating oxide film 39 (other oxide film) which is stacked on the interface oxide film 29.

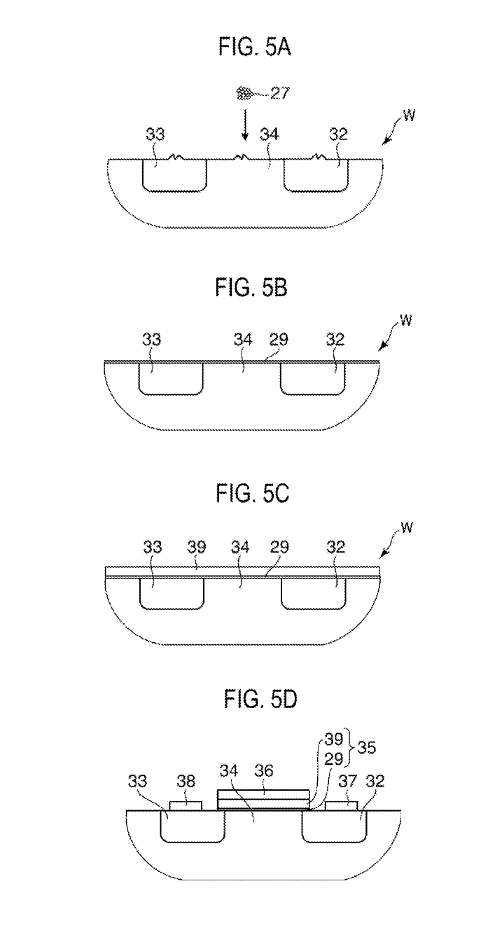

FIGS. 5A to 5D are process diagrams illustrating a transistor manufacturing method according to the present embodiment.

In FIGS. 5A to 5D, after cutting the wafer W from a Sic ingot, the surface layer of the wafer W is polished with abrasive grain. Then, by doping impurities onto the surface layer of the wafer W, the drain area 32 and the source area 33 are formed.

Next, the GCIB irradiation apparatus 13 irradiates the oxygen-GCIB 16 including the oxygen gas cluster 27 onto the surface layer of the wafer W (FIG. 5A). At this time, as described above, removal of the protrusion portions at the molecular level from the surface layer of wafer W is possible by a lateral sputtering with the oxygen gas cluster 27. The interface oxide film 29 is formed on the drain area 32, the source area 33 and the channel area 34 interposed between them by oxidation of silicon carbide. Then, the accelerated bonding of carbon in the wafer W and oxygen from the oxygen gas cluster 27 allows carbon to be emitted from the interface oxide film 29 (FIG. 5B).

Subsequently, the coating oxide film 39 made of silicon carbide or the like is formed by way of a CVD method or the like on the interface oxide film 29 (FIG. 5C). Then, the transistor manufacturing method is completed by forming the gate oxide film 35, the gate electrode 36, the drain electrode 37 or the source electrode 38 through lithography or metal film formation (FIG. 5D).

According to the transistor manufacturing method of the present embodiment, the oxygen-GCIB 16 including the oxygen gas cluster 27 is irradiated onto the surface layer of the wafer W. The oxygen-GCIB 16 has an effect of lateral sputtering in which the oxygen molecule 28 decomposed from the oxygen gas cluster 27 actively sputters the protrusion portion protruded on the wafer W. Therefore, the oxygen-GCIB 16 can remove the protrusion portion at a molecular level from the surface layer of the wafer W.

Further, since the interface oxide film 29 is formed by oxidation of silicon carbide and, at the same time, carbon is emitted from the interface oxide film 29 because of the accelerated combination of carbon in the wafer W and oxygen from the oxygen gas cluster 27, carbon hardly ever exists in the interface oxide film 29. Accordingly, there is no possibility that smoothing the interface between the interface oxide film 29 and the channel area 34 is disrupted by impurities which is produced by the combination of the carbon residue with other elements.

As a result, it is possible to keep the interface state density of the channel area 34 low in the surface of the wafer W and to prevent a decrease of channel mobility. Therefore it is possible to prevent the channel area 34 from decreasing in conductance.

A test was conducted to figure out the relation between acceleration voltage and the remaining interface oxide film. According to the test in which an oxygen-GCIB is irradiated onto the surface layer of a substrate made of silicon carbide at acceleration voltages of 5 kV, 10 kV and 20 kV, it was confirmed that an oxide film is formed on the surface layer of the substrate and the thickness of the oxide film increases as the acceleration voltage increases. Further, it showed that an interface oxide film 29 obtained as a result is thin since oxygen molecules or oxygen elements decomposed by the oxygen-GCIB penetrates the substrate up to only a shallow portion.

Considering the test results, in the transistor manufacturing method according to the present embodiment, the gate oxide film 35 is obtained by placing the coating oxide film 39 on the interface oxide film 29 by way of a CVD method or the like, which enables a gate oxide film having a desired thickness to be obtained easily and clearly. Further, since forming the interface oxide film 29 by the irradiation of the oxygen-GCIB 16 is performed only at a region near the interface and the coating oxide film 39 is formed in other regions by arbitrary manufacturing methods, which also increases the efficiency of forming the gate oxide film 35.

However, in the manufacturing method in FIGS. 5A to 5D, if the size of unevenness on the surface layer after polishing the surface layer of the wafer W by abrasive grain is a little big, one irradiation of the oxygen-GCIB 16 may not remove the unevenness on the surface layer. In this case, the irradiation of the oxygen-GCIB 16 may be repeated a plurality of times.

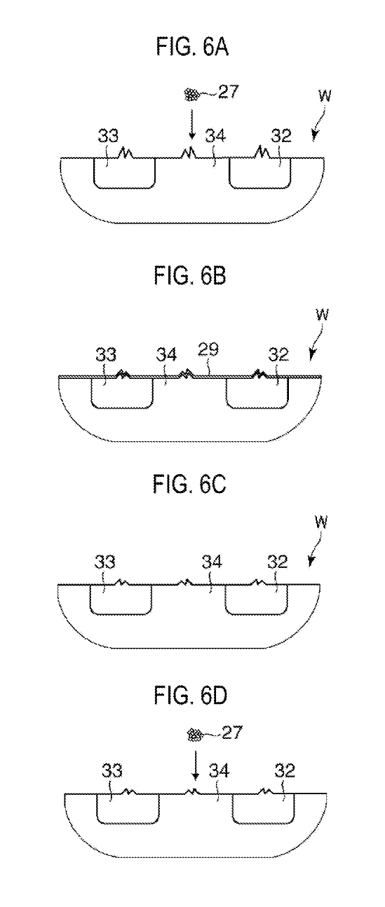

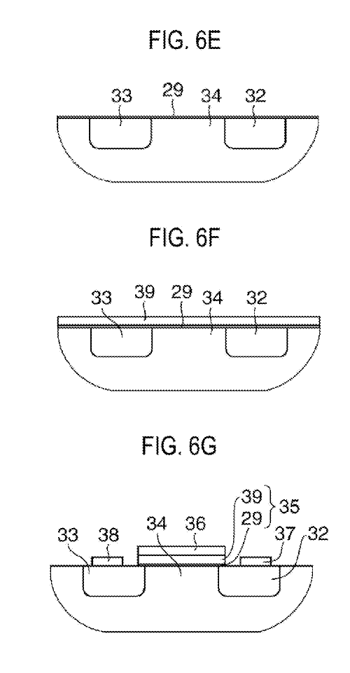

For example, as shown in FIGS. 6A to 6G, the oxygen-GCIB 16 is irradiated on the surface layer of the wafer W polished by the abrasive grain, in which the drain area 32 and the source area 33 are formed (FIG. 6A). Thus, the unevenness on the surface layer can be reduced by lateral sputtering with the oxygen gas cluster 27. At the same time, the interface oxide film 29 is directly formed on the drain area 32, the source area 33 and the channel area 34 (FIG. 6B).

Next, the interface oxide film 29 is removed using wet etching with HF (Hydrofluoric Acid) or dry etching with HF gas (as process gas). Then a surface of the wafer W having reduced unevenness is exposed (FIG. 6C).

Next, the irradiation of the oxygen-GCIB 16 is conducted again on the surface layer of the wafer W (FIG. 6D). Then, the protrusion portions at the molecular level are removed from the wafer W by lateral sputtering with the oxygen gas cluster 27. At the same time, the interface oxide film 29 is directly formed on the drain area 32, the source area 33 and the channel area 34 (FIG. 6E).

Next, the coating oxide film 39 is formed on the interface oxide film 29 (FIG. 6F). Then, the gate oxide film 35, the gate electrode 36, the drain electrode 37 and the source electrode 38 are formed by means of lithography or metal film formation.

Since there is a possibility that the interface oxide film 29 is formed on the channel area 34 before the unevenness on the surface layer of the wafer W is completely removed by the first irradiation of the oxygen-GCIB 16 and the interface oxide film 29 restrains the lateral sputtering with the oxygen gas cluster 27, the interface oxide film 29 is removed before the next irradiation of the oxygen-GCIB 16 and then the surface layer of the wafer W is exposed in the transistor manufacturing method in FIGS. 6A to 6G. Thus, even though the irradiation of the oxygen-GCIB 16 is repeated, suppression of the lateral sputtering by the oxygen gas cluster 27 can be prevented.

On the other hand, it is not necessary for the interface oxide film 29 to be thick in smoothing the interface between the interface oxide film 29 and the channel area 34. Even an interface oxide film 29 having a thickness of, e.g., several nm, will be sufficient as long as it hardly ever has carbon therein and is directly formed on the channel area 34. In other words, the interface oxide film 29 formed by the final irradiation of the oxygen-GCIB 16 has only to remain. Therefore, removing other interface oxide films 29 except for the interface oxide film 29 which is formed by the final irradiation of the oxygen-GCIB 16 does not cause any problems in view of smoothing the interface.

As described above, in the transistor manufacturing method shown in FIGS. 6A to 6G, the interface oxide films 29 except for the interface oxide film 29 formed by the final irradiation of the oxygen-GCIB 16 are removed.

In the transistor manufacturing method shown in FIGS. 6A to 6G, although forming the interface oxide film 29 by the irradiation of the oxygen-GCIB 16 is performed twice, during which the removal of the interface oxide film 29 is conducted once, and lastly the coating oxide film 39 is formed on the interface oxide film 29, the numbers of forming the interface oxide film 29 and removing the interface oxide film 29 are not limited to the transistor manufacturing method shown in FIGS. 6A to 6G. For example, in some embodiments, an interface oxide film forming/removing process forming the interface oxide film and removing the interface oxide film as one cycle thereof is repeated. In a final cycle of the process, the interface oxide film 29 is not removed and the coating oxide film 39 is formed on the interface oxide film 29.

Although the present disclosure has been described with the above embodiment, it is not limited to the above embodiment.

For example, the MOSFET 30 described above has the flat plate-shaped gate electrode. However, there can be a three-dimensional gate electrode with a V-shaped groove or a U-shaped groove. The V-shaped groove or U-shaped groove of a wafer is formed using dry etching. The dry etching may leave damage or unevenness on the surface layer of the V-shaped groove or U-shaped groove. When using the substrate processing apparatus 10 for removing the damage or unevenness, the GCIB irradiation apparatus 13 faces the wafer holding unit 12 in a face to face manner whereas the surface layer of the V-shaped or U-shaped groove doesn't face the GCIB irradiation apparatus 13 in a face to face manner, which results in the oxygen-GCIB 16 being obliquely irradiated to the surface layer of the V-shaped groove or U-shaped groove.

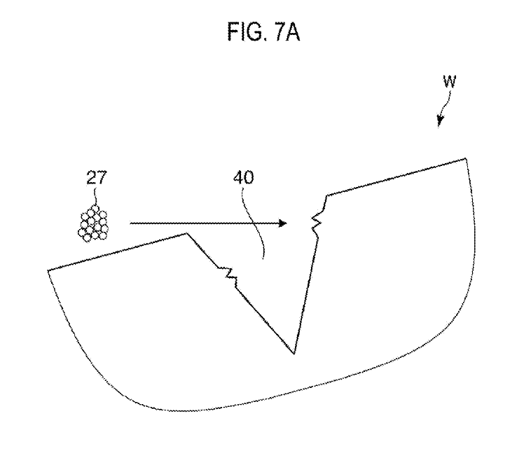

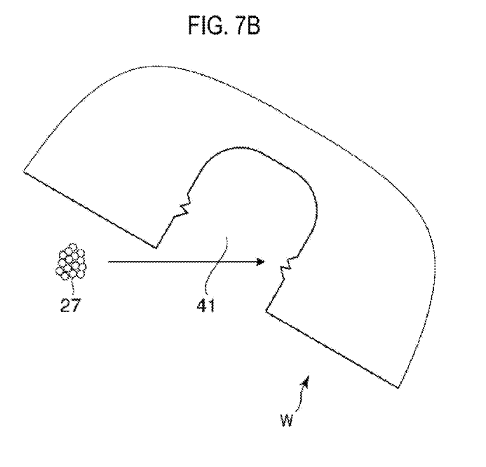

In this case, the oxygen molecules 28 decomposed from the oxygen gas cluster 27 may not be scattered to all direction equally, but scattered to one direction only, which results in that the damage or the unevenness on the surface layer of the V-shaped groove or U-shaped groove may not be sputtered. To resolve the shortcoming, it is preferable in some embodiments that the stage 14 be tiltably installed with respect to the base 15 in order to make the surface layer of the V-shaped groove 40 or the U-shaped groove 41 face the GCIB irradiation apparatus 13 in a face to face manner by tilting the wafer W held on the stage 14 with respect to the oxygen-GCIB 16 (FIGS. 7A and 7B).

In this way, the oxygen molecules 28 decomposed from the oxygen gas cluster 27 can be scattered in all direction equally on the surface layer of the V-shaped groove 40 or the U-shaped groove 41, whereby the damage or unevenness on the surface layer of the V-shaped groove 40 or the U-shaped groove 41 can be clearly sputtered and removed.

In some embodiments, after forming the interface oxide film 29, the interface oxide film 29 can be modified by heat treatment on the wafer W at a temperature of 500 to 1300 degrees C. The atmosphere around the wafer W may be composed of inert gas or oxygen gas. This can prevent the generation of impurities, e.g., nitrogen compound in the interface oxide film 29.

The present disclosure can be implemented by providing a computer, e.g., a controller of the substrate processing apparatus 10, with a storage medium in which program codes of software that perform functions of the above mentioned embodiments are recorded, and by decoding the program codes recorded in the storage medium by CPU of the controller.

In this case, the program code read from the storage medium implements the functions of the above mentioned embodiment. Accordingly, the storage medium storing the program codes constitutes the present disclosure.

As long as the storage medium can store the program codes, the storage medium may be various ones such as a RAM, a NVRAM, a floppy disk (registered trademark), a hard disk, a opto-magnetic disk, a CD-ROM, a CD-R, a CD-RW, an optical disk (e.g., a DVD (a DVD-ROM, a DVD-RAM, a DVD-RW, or a DVD+RW)), a magnetic tape, a non-volatile memory card, other ROMs and so forth. Alternatively, the program code may be provided to the controller through a download from other computers or database (not shown) connected to internet, commercial internet, or local area network.

The functions described in the above-mentioned embodiment can be implemented by running the program codes read by the controller. In addition, the functions can be implemented by allowing an OS (Operating System) running in the CPU to execute partial or all of practical processes based on instructions from the program codes.

The functions described in the aforementioned embodiment can also be implemented by allowing a function expansion board or CPU in a function expansion unit to execute partial or all practical processes based on instructions from the program codes, wherein the program code read from the storage medium is recorded on a memory in the function expansion board inserted in the controller or the function expansion unit connected to the controller.

The program code may be in a form of object code, program code run by an interpreter, script data supplied to the OS or the like.

According to the transistor manufacturing method of the present disclosure, an oxygen-GCIB is irradiated onto the surface layer of the substrates made of silicon carbide and includes a portion to become a channel. When the GCIB is smashed on the surface layer of the substrate, the GCIB is decomposed into molecules and elements and the decomposed molecules and elements give an effect of lateral sputtering in which they actively sputter the protrusion portions protruded on the wafer. Therefore, the protrusion portion with a molecular level size can be removed from the surface layer of the wafer. Thus, it is possible to keep the interface state density low and prevent a decrease in channel mobility.

Further, sputtering by an oxygen gas cluster of the oxygen-GCIB can remove damage on the surface layer of the substrate.

In addition, when the oxygen-GCIB is irradiated onto the surface layer of the substrate, an oxide film is formed by oxidation of silicon carbide and carbon is emitted as carbon dioxide (CO₂) since the bonding of carbon and oxygen on the surface layer of the substrate is accelerated by energy of the oxygen gas cluster. Thus, carbon hardly ever remains in the oxide film. Therefore, it is possible to keep the interface state density low and prevent a decrease in the channel mobility.

As a result, it is possible to prevent a decrease in channel conductance.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for manufacturing a transistor comprising irradiating an oxygen gas cluster ion beam onto a surface layer of a substrate made of silicon carbide and including a channel area to become a channel to form a thin interface oxide film.

2. The method of claim 1, further comprising: forming a gate oxide film by forming an oxide film on the thin interface oxide film.

3. The method of claim 1, further comprising:
repeating a process of forming the thin interface oxide film and removing the thin interface oxide film as one cycle thereof; and
forming an oxide film on the thin interface oxide film formed in a final cycle of the process to form a gate oxide film.

4. The method of claim 1, further comprising tilting the substrate to irradiate the oxygen gas cluster ion beam onto the entire channel area in the substrate, if a gate electrode does not have a flat plate shape.

5. A transistor, comprising:
a channel area to become a channel; and
a gate oxide film formed on the channel area,
wherein the gate oxide film includes a thin interface oxide film formed on the channel area and an oxide film formed on the thin interface oxide film,
wherein the thin interface oxide film is formed by irradiation of an oxygen gas cluster ion beam onto a surface layer of a substrate made of silicon carbide and including the channel area.

6. The transistor of claim 5, wherein the gate oxide film is formed by repeating a process of forming the thin interface oxide film and removing the thin interface oxide film as one cycle thereof and by forming the oxide film on the thin interface oxide film formed in a final cycle of the process.
